(19) United States
(12) Patent Application Publication
(10) Pub. No.: US 2024/0222387 A1
(43) Pub. Date: Jul. 4, 2024

(54) Display Device

(71) Applicant: LG Display Co., Ltd., Seoul (KR)

(72) Inventors: Minseok Kim, Seoul (KR); Juhyun Nam, Seoul (KR); Yongmin Ha, Seoul (KR)

(21) Appl. No.: 18/397,931

(22) Filed: Dec. 27, 2023

(30) Foreign Application Priority Data
Dec. 30, 2022 (KR) 10-2022-0190882

(51) Int. Cl. H01L 27/12; H01L 27/15

(52) U.S. Cl. CPC H01L 27/124; H01L 27/1248; H01L 27/156

(57) ABSTRACT

A display device includes a wiring substrate on which a plurality of link wire lines are disposed; a plurality of display units including a plurality of light-emitting elements and a plurality of signal lines, respectively, wherein the plurality of display units are disposed on the wiring substrate and are spaced apart from each other, a plurality of bonding members disposed between the wiring substrate and the plurality of display units, respectively so as to electrically connect the plurality of link wire lines and the plurality of signal lines to each other, respectively; and a refractive index matching layer filling a boundary area between adjacent ones of the plurality of display units.

### CROSS-REFERENCE TO RELATED APPLICATION

This application claims priority from Korean Patent Application No. 10-2022-0190882 filed on Dec. 30, 2022 in the Korean Intellectual Property Office, and all the benefits accruing therefrom under 35 U.S.C. 119, the contents of which in its entirety are herein incorporated by reference.

### BACKGROUND

### Field

The present disclosure relates to a display device. More specifically, the present disclosure relates to a display device capable of reducing visibility in a boundary area between adjacent display units.

### Description of Related Art

A display device is applied to various electronic devices such as TVs, mobile phones, laptops, and tablets. To this end, research to develop thinning, lightening, and low power consumption of the display device is continuing.

Among display devices, a light-emitting display device has a light-emitting element or a light source built therein and displays information using light generated from the built-in light-emitting element or light source. A display device including a self-light-emitting element may be implemented to be thinner than a display device with the built-in light source, and may be implemented as a flexible display device that may be folded, bent, or rolled.

The display device having the self-light-emitting element may include, for example, an organic light-emitting display device (OLED) including a light-emitting layer made of an organic material, or a micro-LED display device (micro light-emitting diode display device) including a light-emitting layer made of an inorganic material. In this regard, the organic light-emitting display device does not require a separate light source. However, due to material characteristics of the organic material that is vulnerable to moisture and oxygen, a defective pixel easily occurs in the organic light-emitting display device due to an external environment. On the contrary, the micro-LED display device includes the light-emitting layer made of the inorganic material that is resistant to moisture and oxygen and thus is not affected by the external environment and thus has high reliability and has a long lifespan compared to the organic light-emitting display device.

### SUMMARY

Since the micro-LED display device is resistant to the external environment, the micro-LED display device does not require a protective structure such as a sealing material, and various types of materials may be used as a material of a substrate of the device, thereby implementing a flexible display device with a thinner structure than that of the organic light-emitting display device. Accordingly, a plurality of micro-LED display devices may be arranged in first and second horizontal directions intersecting each other to implement a large-area tiling display apparatus.

When the tiling display apparatus is implemented by arranging a plurality of micro-LED display devices in the first and second horizontal directions intersecting each other, a structure for blocking a non-display area surrounding a display area from the user's field of view, for example, a bezel, is disposed. However, as a width of the bezel increases, the bezel may be recognized by the user to lower image immersion. Thus, research is being conducted to form a minimum bezel area.

Further, a technical purpose according to an exemplary embodiment of the present disclosure is to provide a large-area display device by arranging a plurality of display units on an upper surface of a wiring substrate.

Moreover, a technical purpose according to an exemplary embodiment of the present disclosure is to provide a transparent display device in which a boundary area between adjacent display units is prevented or reduced from being visible to a user.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display device according to an exemplary embodiment of the present disclosure includes a wiring substrate on which a plurality of link wire lines are disposed; a plurality of display units including a plurality of light-emitting elements and a plurality of signal lines, respectively, wherein the plurality of display units are disposed on the wiring substrate and are spaced apart from each other; a plurality of bonding members each disposed between the wiring substrate and a corresponding one of the plurality of display units, so as to electrically connect corresponding one or more of the plurality of link wire lines and corresponding one or more of the plurality of signal lines to each other; and a refractive index matching layer filling a boundary area between adjacent ones of the plurality of display units.

According to the embodiment of the present disclosure, the bezel area may be disposed in a minimum space or a zero bezel area in which substantially no bezel area exists may be realized.

Moreover, the wiring substrate and each of the plurality of display units are electrically connected to each other and are bonded to each other using the bonding member. Thus, a plurality of processes for forming a side surface line may be omitted such that the process optimization may be realized.

Moreover, the boundary area between adjacent display units may be filled with the refractive index matching layer including a material having a refractive index and transparency similar to those of the base substrate of the display unit, thereby reducing the visibility of the boundary area to improve the user's image immersion.

Moreover, the sealing member may be bonded to the outermost area of the wiring substrate to prevent permeation of the moisture from the outside into the display units such that a coupling strength between the wiring substrate and the plurality of display units may be improved.

In another embodiment, a display device comprises a plurality of display units including a first display unit and a second display unit disposed laterally spaced apart from the first display unit, each of the first and second display units comprising: a plurality of sub-pixels each including one or more micro-LEDs including inorganic material and a plurality of signal lines; and a plurality of transmissive areas adjacent to the sub-pixels, the transmissive areas configured to transmit external light from a first side of the display device to a second side of the display device.

In still another embodiment, a display device comprises a plurality of display units including a first display unit and a second display unit disposed laterally spaced apart from the first display unit, each of the first and second display units comprising: a substrate on which a plurality of thin film transistors are disposed; a passivation layer disposed on the thin film transistors and including insulating material; an adhesive layer disposed on at least a part of the passivation layer; one or more micro-LED chips each including a micro-LED made of inorganic material and attached to the passivation layer by the adhesive layer; one or more protective patterns each disposed on a side surface or at least a part of a top surface of the micro-LED chip.

Effects of the present disclosure are not limited to the effects mentioned above, and other effects not mentioned will be clearly understood by those skilled in the art from the descriptions below.

### BRIEF DESCRIPTION OF DRAWINGS

FIG. 1 is a schematic plan view of a display device according to an exemplary embodiment of the present disclosure.

FIG. 2 is a schematic plan view of a wiring substrate according to an exemplary embodiment of the present disclosure.

FIG. 3 is a cross-sectional view taken along a line 3-3 in FIG. 2.

FIG. 4 is a schematic enlarged plan view of an area 4 in FIG. 1.

FIG. 5 is a cross-sectional view taken along a line 5-5 in FIG. 4.

FIG. 6 is a schematic cross-sectional view of a display device according to an embodiment of the present disclosure.

FIG. 7 is a schematic cross-sectional view of a display device according to another exemplary embodiment of the present disclosure.

FIG. 8 is a schematic cross-sectional view of a display device according to still another exemplary embodiment of the present disclosure.

FIG. 9 is a cross-sectional view of a display device according to an exemplary embodiment of the present disclosure.

FIG. 10 is a cross-sectional view of a display device according to another exemplary embodiment of the present disclosure.

FIG. 11 is a cross-sectional view of a display device according to still another exemplary embodiment of the present disclosure.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The same reference numerals refer to the same elements herein.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may denote the entire list of elements, may denote the individual elements of the list, or may denote any combination of the elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device according to each exemplary embodiment of the present disclosure will be described with reference to the accompanying drawings.

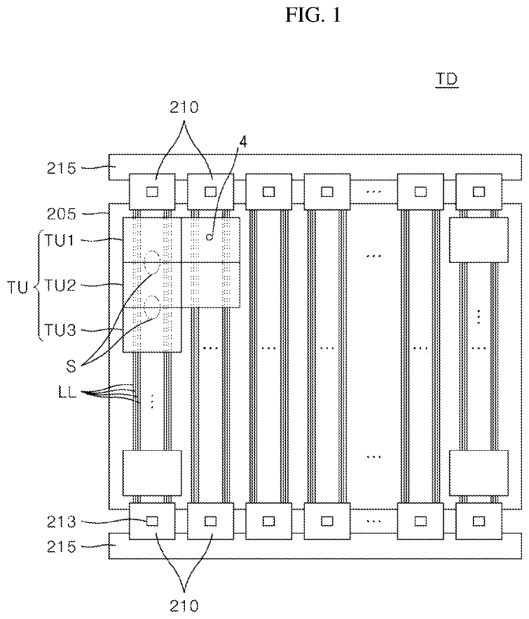

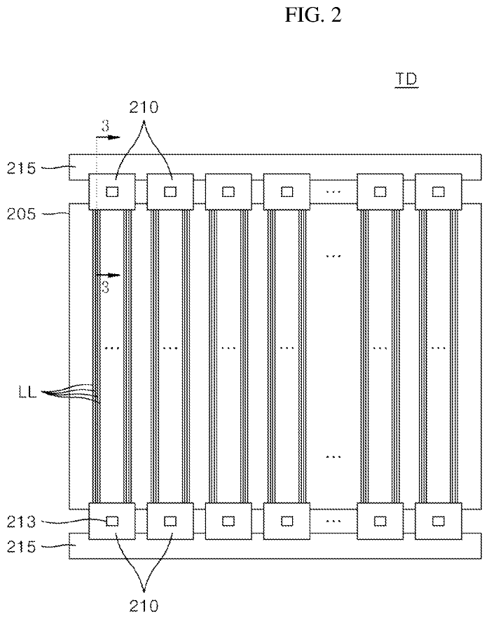

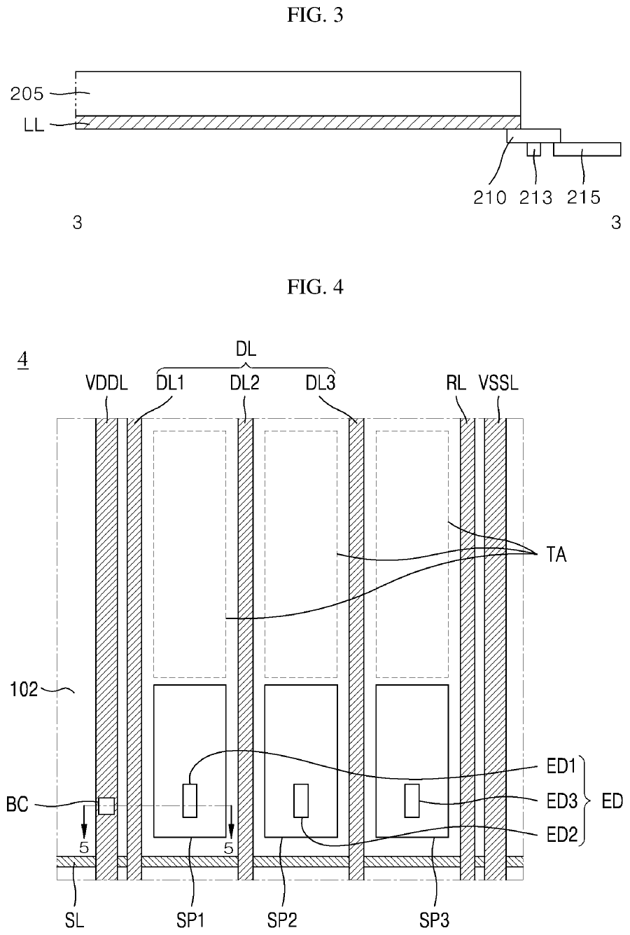

FIG. 1 is a schematic plan view of a tiling display device according to an exemplary embodiment of the present disclosure. FIG. 2 is a schematic plan view of a wiring substrate according to one exemplary embodiment of the present disclosure. FIG. 3 is a cross-sectional view taken along line 3-3 in FIG. 2.

In FIG. 1, for convenience of illustration, among components of a tiling display device TD, only a wiring substrate 205, a plurality of link wire lines LL, a plurality of circuit films 210 on which a plurality of integrated circuit chips 213 are respectively disposed, printed circuit boards 215, and a plurality of display units TU1, TU2, and TU3 are shown. FIG. 2 shows components except for the plurality of display units TU1, TU2, and TU3 among the components shown in FIG. 1.

Referring to FIGS. 1 to 3, the tiling display device TD according to one exemplary embodiment of the present disclosure may include the wiring substrate 205, and the plurality of display units TU1, TU2, and TU3 arranged on the wiring substrate 205. The display units TU1, TU2, and TU3 may be arranged along each of a first direction and a second direction intersecting the first direction. In this regard, the first direction may be a horizontal direction, and the second direction may be a vertical direction. The first direction may be perpendicular to the second direction. The wiring substrate 205 may include glass or transparent plastic.

The plurality of link wire lines LL may be disposed on the wiring substrate 205. The plurality of link wire lines LL may extend along one direction of the wiring substrate 205. A driver may be disposed on each of both opposing side ends of the wiring substrate 205. The driver may include each of the printed circuit boards 215 connected to each of the circuit films 210 on which each of the integrated circuit chips 213 is mounted. Each of the circuit films 210 is connected to each of ends of the link wire lines LL. The driver (not shown) may transmit various signals to sub-pixels of each display unit TU. For example, the signals transmitted to the sub-pixels may include a high-potential voltage, a low-potential voltage, a scan signal, or a data signal. In an embodiment of the present disclosure, a configuration in which each driver including each of the printed circuit boards 215 connected to each of the circuit films 210 on which each of the integrated circuit chips 213 is mounted is disposed at each of both opposing side ends of the wiring substrate 205 is illustrated. However, the present disclosure is not limited thereto.

The plurality of link wire lines LL may deliver various signals delivered from the driver to the plurality of signal lines disposed in each of the display units TU1, TU2, and TU3. For example, the signal lines may include, but are not limited to, a high-potential voltage line, a low-potential voltage line, a scan line, and a data line.

Each of the plurality of display units TU1, TU2, and TU3 disposed on the wiring substrate 205 may be connected to the wiring substrate 205 via an electrical connection between each of a plurality of signal lines and the plurality of link wire lines LL disposed in the wiring substrate 205. In this regard, the plurality of link wire lines LL may be disposed to overlap the plurality of display units TU1, TU2, and TU3, respectively, and may not be exposed to the outside. As a result, an area size of the circuit area in which the plurality of link wire lines LL are disposed may be reduced and thus the display area may be increased.

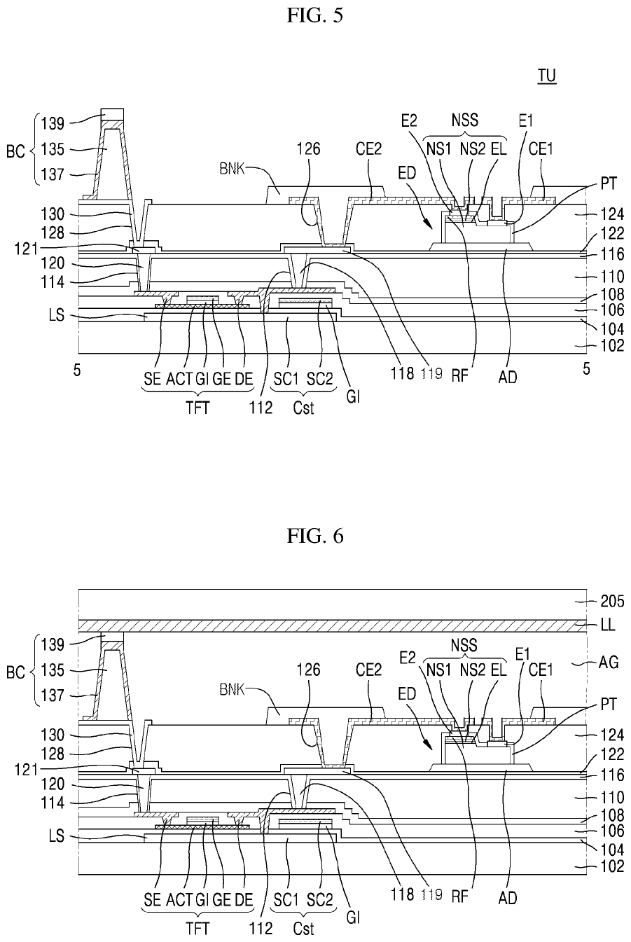

A plurality of pixels may be disposed in each of the plurality of display units TU1, TU2, and TU3. A light-emitting element and a driving circuit including a transistor for driving the light-emitting element may be disposed in each of the plurality of pixels. This will be described with reference to FIG. 4 and FIG. 5 below.

FIG. 4 is a schematic enlarged plan view of an area 4 of FIG. 1 of the display device according to one exemplary embodiment of the present disclosure. FIG. 5 is a cross-sectional view taken along a line 5-5 in FIG. 4. FIG. 4 is an enlarged plan view of a portion of an area corresponding to a pixel disposed in a display unit.

Referring to FIG. 4, each of the plurality of pixels may include a plurality of sub-pixels SP1, SP2, and SP3. The plurality of sub-pixel SP1, SP2, and SP3 may include the first sub-pixel SP1, the second sub-pixel SP2, and the third sub-pixel SP3.

Each of the sub-pixels SP1, SP2, and SP3 may include a light-emitting area and a circuit area for driving the light-emitting area. The light-emitting area may include a first light-emitting element ED1, a second light-emitting element ED2, and a third light-emitting element ED3 emitting light of different colors of red (R), green (G), and blue B, respectively. The light-emitting area may refer to an area in which light emitted from the first to third light-emitting elements ED1, ED2, and ED3 may be emitted to the outside. The light-emitting area may further include a white light-emitting element emitting white light. A light-emitting element according to an exemplary embodiment of the present disclosure may be embodied as a micro-LED (a Micro Light Emitting Diode). The micro-LED may be a LED made of an inorganic material, and may refer to a light-emitting element with a thickness of 100 μm or smaller or free of a growth substrate for growing the LED.

The circuit area refers to an area other than the light-emitting area. In the circuit area, circuit elements such as a thin-film transistor and a storage capacitor, etc. for driving the first light-emitting element ED1, the second light-emitting element ED2, or the third light-emitting element ED3 may be disposed.

Each of a plurality of transmissive areas TA may be defined in each of the plurality of pixels. The transmissive area TA may be an area in which a non-transparent material or a reflective material is not disposed. The tiling display device TD according to an exemplary embodiment of the present disclosure may secure transmittance of light from the back of the display device to the front of the display device due to the transmissive area TA. Thus, the tiling display device TD may be a transparent display device through which an object disposed of rear of the tiling display device TD may be recognized by a viewer in front of the device.

A plurality of signal lines may be disposed on a base substrate 102. The plurality of signal lines may include a high-potential voltage line VDDL, a low-potential voltage line VSSL, a reference voltage line RL, a data line DL, and a scan line SL.

Each of the high-potential voltage line VDDL and the low-potential voltage line VSSL may supply a driving power for driving the first light-emitting element ED1, the second light-emitting element ED2, or the third light-emitting element ED3. In one embodiment, the high-potential voltage line VDDL is disposed on one side of the sub-pixel SP1 and extend in a column direction along the transmission area TA and the sub-pixel SP1, and the low-potential voltage line VSSL is disposed on another side of the sub-pixel SP3 and extend in a column direction along the transmission area TA and the sub-pixel SP3, as shown in FIG. 4. The reference voltage line RL may deliver a reference voltage to each of the plurality of sub-pixels SP1, SP2, and SP3. In one embodiment, the reference voltage line RL may also be disposed on another side of the sub-pixel SP3 and extend in a column direction along the transmission area TA and the sub-pixel SP3, substantially parallel to the low-potential voltage line VSSL, as shown in FIG. 4.

The data line DL may include a first data line DL1, a second data line DL2, and a third data line DL3. Each of the plurality of data lines DL1, DL2, and DL3 may be disposed on one side of each of the plurality of sub-pixels SP1, SP2, and SP3 and may extend in a column direction along and between the transmission areas TA and the sub-pixels SP1, SP2, SP3, and may supply the data signal to a corresponding one of the plurality of sub-pixels SP1, SP2, and SP3. Each of the plurality of data lines DL1, DL2, and DL3 extend substantially parallel to the high-potential voltage line VDDL, the low-potential voltage line VSSL, the reference voltage line DL, The transmissive areas TAs are disposed adjacent to each of the sub-pixels SP1, SP2, SP3 in between the data lines DL1, DL2, DL3 and the reference voltage line RL.

The scan line SL may extend in a row direction intersecting the data line DL and may supply the scan signal to each of the plurality of sub-pixels SP1, SP2, and SP3.

The signal lines including the high-potential voltage line VDDL, the low-potential voltage line VSSL, the reference voltage line RL, the data line DL, and the scan line SL may be connected to the wiring substrate 205 via electrical connections thereof to the plurality of link wire lines LL disposed in the wiring substrate 205, respectively. For example, the signal lines may be electrically connected to the link wire line LL on the wiring substrate 205 via a bonding member BC.

In one embodiment of the present disclosure, for convenience of illustration, a configuration in which the bonding member BC overlaps with the high-potential voltage line VDDL is illustrated by way of example. However, the present disclosure is not limited thereto. For example, the bonding member BC may overlap with the low-potential voltage line VSSL, the reference voltage line RL, the data line DL or the scan line SL.

Hereinafter, various components of the display unit including the bonding member BC will be described with reference to FIG. 5.

Referring to FIG. 5, the display unit TU according to one exemplary embodiment of the present disclosure may include a base substrate 102, and a thin-film transistor TFT, a storage capacitor Cst, various lines, and the bonding member BC disposed on the base substrate 102. The thin-film transistor TFT may drive the light-emitting element ED, and the storage capacitor Cst may store a voltage therein so that the light-emitting element ED continues to maintain the same state during one frame. The base substrate 102 may be made of a transparent material including glass or plastic.

A light-blocking layer LS may be disposed on the base substrate 102. The light-blocking layer LS may prevent or reduce light incident from the base substrate 102 from invading a semiconductor layer ACT of a transistor to reduce leakage current. For example, the light-blocking layer LS may be disposed under the semiconductor layer ACT of the thin-film transistor TFT functioning as a driving transistor so as to prevent or reduce light from being incident to the semiconductor layer ACT.

A buffer layer 104 is disposed on the light-blocking layer LS. The buffer layer 104 may block impurities or moisture flowing through the base substrate 102. The buffer layer 104 may include, for example, an insulating material such as silicon oxide (SiOx) or silicon nitride (SiNx).

The thin-film transistor TFT is disposed on the buffer layer 104. The thin-film transistor TFT may include the semiconductor layer ACT, a gate electrode GE, a source electrode SE, and a drain electrode DE. A gate insulating layer GI may be disposed between the semiconductor layer ACT and the gate electrode GE.

The semiconductor layer ACT may include an active area overlapping the gate electrode GE to constitute a channel, and a source area and a drain area disposed respectively on both opposing sides of the active area disposed therebetween. An interlayer insulating film 106 is disposed on the gate electrode GE. The interlayer insulating film 106 may receive therein a source electrode SE and a drain electrode DE which may be respectively electrically connected to the source and drain areas of the semiconductor layer ACT. Each of the source electrode SE and the drain electrode DE may be made of a conductive material such as copper (Cu), aluminum (Al), molybdenum (Mo), nickel (Ni), titanium (Ti), chromium (Cr), or an alloy thereof. However, the present disclosure is not limited thereto.

The storage capacitor Cst may include a first capacitor electrode SC1 and a second capacitor electrode SC2. The first capacitor electrode SC1 may be disposed between the base substrate 102 and the buffer layer 104. The first capacitor electrode SC1 may be formed integrally with the light-blocking layer LS. The buffer layer 104 and the gate insulating layer GI may be disposed on the first capacitor electrode SC1 and may act as a dielectric layer. The second capacitor electrode SC2 may be disposed on the gate insulating layer GI. The second capacitor electrode SC2 may be made of the same material as that of the gate electrode GE.

A first passivation layer 108 is disposed on the source electrode SE and the drain electrode DE. The first passivation layer 108 serves to protect the thin-film transistor TFT and may include an insulating material. A first planarization layer 110 is disposed on the first passivation layer 108. The first planarization layer 110 serves to remove a surface step caused by an underlying component such as the thin-film transistor TFT. The first planarization layer 110 may include a photoactive compound (PAC). However, the present disclosure is not limited thereto.

The first planarization layer 110 may have contact-holes 112 and 114 defined therein respectively exposing portions of surfaces of the drain electrode DE and the source electrode SE. The contact-holes 112 and 114 may include the first contact-hole 112 extending through the first planarization layer 110 and the first passivation layer 108 so as to expose the portion of the surface of the drain electrode DE, and the second contact-hole 114 extending through the first planarization layer 110 and the first passivation layer 108 so as to expose the portion of the surface of the source electrode SE.

A second passivation layer 116 including an insulating material may be disposed on the first planarization layer 110. A first via contact 118 may fill the first contact-hole 112 while a second via contact 120 may fill the second contact-hole 114. A connection electrode 119 and a signal line 121 respectively connected to the first and second via contacts 118 and 120 may be disposed on the second passivation layer 116.

The via contacts 118 and 120 may include the first via contact 118 and the second via contact 120. One surface of the first via contact 118 may be connected to the drain electrode DE and the other surface thereof may be connected to the connection electrode 119. Moreover, the drain electrode DE may be electrically connected to the light-blocking layer LS via a via hole extending through the interlayer insulating film 106 and the buffer layer 104. One surface of the second via contact 120 may be connected to the source electrode SE and the other surface thereof may be connected to the signal line 121.

Moreover, the second via contact 120 may be electrically connected to the link wire line of the wiring substrate via the bonding member BC and thus the link wire line may be electrically connected to the thin-film transistor TFT. This will be further described later.

The signal line 121 may include a plurality of signal lines. For example, the plurality of signal lines 121 may include a plurality of scan lines SL, a plurality of high-potential power lines VDDL, a plurality of data lines DL, and a plurality of reference voltage lines RL. The plurality of signal lines 121 may be disposed in the same plane on the base substrate 102. Moreover, the plurality of signal lines 121 may be made of the same material as that of each of the first via contact 118 and the second via contact 120.

A third passivation layer 122 covering the connection electrode 119, the signal line 121 and the second passivation layer 116 is disposed. The third passivation layer 122 may expose a portion of an upper surface of each of the connection electrode 119 and the signal line 121.

An adhesive layer AD is disposed on the third passivation layer 122. The adhesive layer AD serves to adhere the light-emitting element ED. The adhesive layer AD may be made of a heat curable material or a light curable material. However, the present disclosure is not limited thereto. While the adhesive layer AD is shown as disposed on the third passivation layer 122 only under the micro-LED in the embodiment shown in FIG. 5, in other embodiments, the adhesive layer AD may be disposed on the entire passivation layer 122.

A light-emitting element ED may be disposed on the adhesive layer AD. The light-emitting element ED according to an exemplary embodiment of the present disclosure may be embodied as a micro-LED. The micro-LED may be an LED made of an inorganic material and may be understood as a light-emitting element of 100 μm or smaller. Moreover, in an embodiment of the present disclosure, an example in which the light-emitting element ED is embodied as a horizontal type micro-LED is described. However, the present disclosure is not limited thereto. For example, the light-emitting element may be embodied as a vertical type micro-LED, a flip-chip shaped micro-LED, or a nanorod-shaped micro-LED.

The light-emitting element ED may include a nitride semiconductor structure NSS, a first electrode E1 and a second electrode E2. The nitride semiconductor structure NSS may include a first semiconductor layer NS1, an active layer EL disposed on one side of an upper surface of the first semiconductor layer NS1, a second semiconductor layer NS2 disposed on the active layer EL, and a reflective layer RF. The first electrode E1 is disposed on the other side of the upper surface of the first semiconductor layer NS1 where the active layer EL is not disposed. The second electrode E2 is disposed on the second semiconductor layer NS2.

The first semiconductor layer NS1 is a layer for supplying electrons to the active layer EL, and may include a nitride semiconductor containing a first conductivity type impurity. For example, the first conductivity-type impurity may include an N-type impurity. The active layer EL disposed on one side of the upper surface of the first semiconductor layer NS1 may include a multi-quantum well (MQW) structure. The second semiconductor layer NS2 is a layer for injecting holes into the active layer EL. The second semiconductor layer NS2 may include a nitride semiconductor containing a second conductivity type impurity. For example, the second conductivity type impurity may include a P-type impurity.

The reflective layer RF serves to reflect the light emitted from the light-emitting element ED toward the light-emitting area. The reflective layer RF may include a metal material with high reflectance. For example, a metal material with high reflectance may have a single-layer structure or a stack structure made of any one material selected from aluminum (Al), copper (Cu), silver (Ag), molybdenum (Mo), gold (Au), magnesium (Mg), calcium (Ca), or barium (Ba), or an alloy of at least two thereof.

The light-emitting element ED may be covered with a second planarization layer 124. The second planarization layer 124 covers part of the light-emitting element ED in the embodiment shown in FIG. 5. In other embodiments, the second planarization layer 124 may cover the entire light-emitting element ED. The second planarization layer 124 may have a thickness sufficient to planarize a stepped upper surface caused by the underlying circuit elements. The second planarization layer 124 may have opening holes 126 and 128 defined therein. The opening holes 126 and 128 may include the first opening hole 126 and the second opening hole 128. Moreover, the second planarization layer 124 may not cover a portion of an upper surface of each of the first electrode E1 and the second electrode E2 of the light-emitting element ED so as to be exposed. The first electrode E1 and the second electrode E2 may be electrically connected to a first line electrode CE1 and a second line electrode CE2, respectively. The second line electrode CE2 may extend along and on an exposed surface of the first opening hole 126. The second line electrode may be electrically connected to the drain electrode DE via the connection electrode 119.

The bank BNK may be disposed on the second planarization layer 124. The bank BNK may include an opaque material. However, the present disclosure is not limited thereto. In one example, the bank BNK may be formed to cover the first line electrode CE1 and the second line electrode CE2. The first opening hole 126 may be filled with a material that constitute the bank BNK. The bank BNK is black, including black pigments to absorb light. The bank BNK fills the contact hole 128, contacting the bottom and side and top edges of the contact hole 128.

The protective layer PT is disposed on sides and a part of the top surface of the light-emitting element ED as shown in FIGS. 5 and 6. The protective layer PT is made of inorganic material and helps with adhesion of the second planarization layer 124 to the light-emitting element ED. Example inorganic materials of the protective layer PT may include an insulating material such as silicon oxide (SiOx).

An interlayer wiring line 130 may be disposed on an exposed surface of the second opening hole 128. One surface of the interlayer wiring line 130 may be connected to the signal line 121 and the other surface thereof may extend along the exposed surface of the second opening hole 128 and extend along and on an upper surface of the second planarization layer 124. The interlayer wiring line 130 may be connected to the source electrode SE via the second via contact 120 connected to the signal line 121.

The first line electrode CE1, the second line electrode CE2, and the interlayer wiring line 130 may be disposed in the same layer and made of the same conductive material. In one example, each of the first line electrode CE1, the second line electrode CE2 or the interlayer wiring line 130 may include a transparent metal oxide such as indium-tin-oxide (ITO) or indium-zinc-oxide (IZO). However, the present disclosure is not limited thereto.

The bonding member BC may be disposed on the interlayer wiring line 130. The bonding member BC may include a spacer pattern 135, a conductive connection pattern 137, and an adhesive pattern 139. The spacer pattern 135 may be disposed on the interlayer wiring line 130, and may include an insulating material. In one example, the spacer pattern 135 may include an insulating material such as silicon oxide (SiOx) or silicon nitride (SiNx). However, the present disclosure is not limited thereto. For example, the spacer pattern 135 and the bank BNK may be formed in the same process and may be made of the same material.

The spacer pattern 135 serves to maintain a gap between the wiring substrate and the display unit TU. The spacer pattern 135 may have a taper shape in which a width of a lower surface thereof contacting the interlayer wiring line 130 is larger than that of an upper surface thereof.

An outer side surface and an upper surface of spacer pattern 135 may be covered with the conductive connection pattern 137. The conductive connection pattern 137 may be disposed to cover the outer side surface of the spacer pattern 135 while covering the upper surface of the spacer pattern 135. Moreover, the conductive connection pattern 137 may extend so as to contact the interlayer wiring line 130. The conductive connection pattern 137 may include, but is not limited to, a conductive material such as copper (Cu), aluminum (Al), molybdenum (Mo), nickel (Ni), titanium (Ti), chromium (Cr), or an alloy thereof.

The adhesive pattern 139 may be disposed on a portion of the conductive connection pattern 137 covering the upper surface of the spacer pattern 135. The adhesive pattern 139 may bond and fix the wiring substrate and the display unit TU to each other. The adhesive pattern 139 may include an adhesive material having electrical conductivity so as to electrically connect the wiring substrate and the display unit TU to each other while bonding the wiring substrate and the display unit TU to each other.

As shown in FIG. 1, the display units TU1, TU2, and TU3 may be bonded and connected to each other while contacting each other and being arranged on the wiring substrate 205 along a first direction and a second direction intersecting the first direction. In this regard, the first direction may be a longitudinal direction, and the second direction may be a transverse direction.

Hereinafter, a configuration in which one display unit among the plurality of display units is bonded to the wiring substrate will be described with reference to drawings.

FIG. 6 is a schematic cross-sectional view of a display device according to an exemplary embodiment of the present disclosure. Since the display unit TU in FIG. 6 is the same as the display unit TU in FIG. 5, the same components may be briefly described or descriptions thereof may be omitted.

Referring to FIG. 1 and FIG. 6, the display unit TU may be bonded onto the wiring substrate 205. For example, display unit TU may be disposed so as to overlap the link wire line LL on the wiring substrate 205. The display unit TU may be bonded and fixed onto the link wire line LL of the wiring substrate 205 via the adhesive pattern 139 of the bonding member BC.

The adhesive pattern 139 may be made of an adhesive and electrically-conductive material in order to electrically connect the link wire line LL connected to a driver to the display unit TU while bonding the wiring substrate 205 and the display unit TU to each other.

The adhesive pattern 139 may contact the conductive connection pattern 137 disposed on an outer surface of the spacer pattern 135. Moreover, the conductive connection pattern 137 may contact and be electrically connected to the interlayer wiring line 130. The interlayer wiring line 130 may be connected to the source electrode SE via the second via contact 120 connected to the signal line 121. Thus, a signal transferred from the driver may be transferred to the thin-film transistor TFT and the light-emitting element ED via the bonding member BC connected to the link wire line LL.

A spacing between the wiring substrate 205 and the display unit TU may be maintained by the bonding member BC and may correspond to a height of the bonding member BC. Moreover, an air gap AG may fill a space between the wiring substrate 205 and the display unit TU.

In one example, a filler may be disposed between the wiring substrate 205 and the display unit TU and a configuration of the bonding member BC may be modified. This will be described below with reference to the drawings.

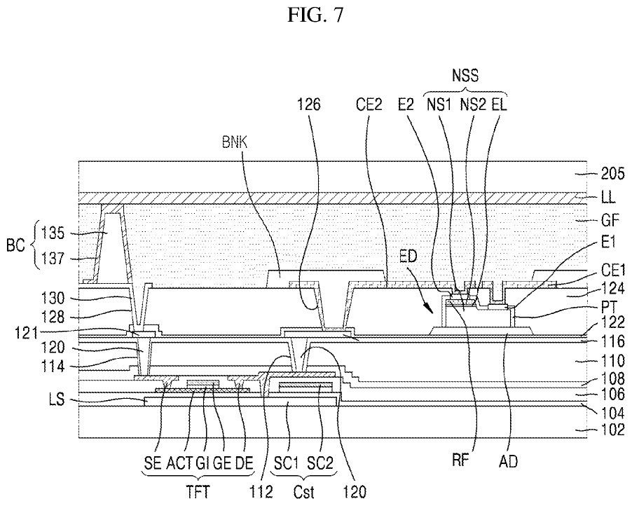

FIG. 7 is a schematic cross-sectional view of a display device according to another exemplary embodiment of the present disclosure. Since the display device according to another exemplary embodiment of the present disclosure is the same as the display device of FIG. 6 except for configurations of the filler and bonding member, differences therebetween will be mainly described, and redundant descriptions will be omitted.

Referring to FIG. 7, in the display device according to another exemplary embodiment of the present disclosure, the display unit TU may be disposed so as to overlap the link wire line LL on the wiring substrate 205. The bonding member BC disposed on the display unit TU may include the spacer pattern 135 and the conductive connection pattern 137 disposed on an outer surface of the spacer pattern 135. Further, the display unit TU may be fixed and bonded to the link wire line LL of the wiring substrate 205 via the conductive connection pattern 137 of the bonding member BC. The conductive connection pattern 137 may include, but is not limited to, a conductive material such as copper (Cu), aluminum (Al), molybdenum (Mo), nickel (Ni), titanium (Ti), chromium (Cr), or an alloy thereof.

Further, a space between the wiring substrate 205 and the display unit TU may be filled with a filler GF made of a transparent material. For example, the filler GF may be formed in an underfill process and may include an epoxy resin. The filler GF may have a sufficient thickness equal to a height of the conductive connection pattern 137 covering the upper surface of the spacer pattern 135 of the bonding member BC. The filler GF together with the bonding member BC may maintain the gap between the wiring substrate 205 and the display unit TU while fixing the wiring substrate 205 and the display unit TU to each other.

In one example, when the spacer pattern 135 of the bonding member BC has the taper shape, the width of the upper surface is smaller than the width of the lower surface. In this case, as the upper surface having a relatively smaller width is in contact with the wiring substrate 205, adhesion thereof to the wiring substrate 205 may deteriorate over time. When the adhesion thereof to the wiring substrate 205 is weakened, this may cause product defects. Therefore, the bonding strength may be improved by modifying a configuration of the bonding member BC. This will be described below with reference to the drawings.

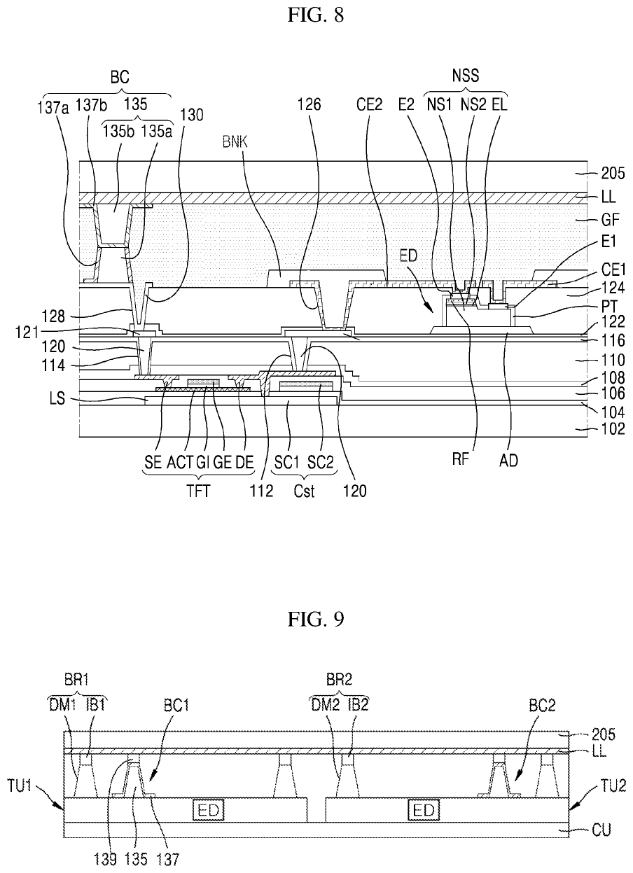

FIG. 8 is a schematic cross-sectional view of a display device according to still another exemplary embodiment of the present disclosure. Since the display device according to still another exemplary embodiment of the present disclosure is the same as the display device of FIG. 7 except for the configuration of the bonding member, the same components may be briefly described or descriptions thereof may be omitted, and differences therebetween will be mainly described, and redundant descriptions will be omitted.

Referring to FIG. 8, in the display device according to still another exemplary embodiment of the present disclosure, the display unit TU may be disposed so as to overlap the link wire line LL on the wiring substrate 205. The bonding member BC disposed on the display unit TU may include a double spacer pattern 135 including a first spacer pattern 135a and a second spacer pattern 135b stacked vertically. The first spacer pattern 135a and the second spacer pattern 135b may include the same insulating material as each other. Alternatively, the first spacer pattern 135a and the second spacer pattern 135b may include different insulating materials.

The first spacer pattern 135a as a lower spacer pattern of the double spacer pattern 135 may have a taper shape in which a width of a lower surface thereof in contact with the interlayer wiring line 130 is larger than a width of an upper surface thereof. The second spacer pattern 135b as an upper spacer pattern of the double spacer pattern 135 may have a reverse taper shape in which a width of an upper surface thereof in contact with the link wire line LL is larger than that of a lower surface thereof. In this regard, the upper surface of the first spacer pattern 135a may face the lower surface of the second spacer pattern 135b.

An outer side surface and an upper surface of the first spacer pattern 135a may be covered with a first conductive connection pattern 137a. An outer side surface and a lower surface of the second spacer pattern 135b may be covered with a second conductive connection pattern 137b. In addition, the first conductive connection pattern 137a and the second conductive connection pattern 137b may contact and be connected to each other at a position where the upper surface of the first spacer pattern 135a and the lower surface of the second spacer pattern 135b face each other.

Each of the first conductive connection pattern 137a and the second conductive connection pattern 137b may be made of a conductive material, for example, copper (Cu), aluminum (Al), molybdenum (Mo), nickel (Ni), titanium (Ti), chromium (Cr) or an alloy thereof. However, the present disclosure is not limited thereto. The first conductive connection pattern 137a and the second conductive connection pattern 137b may include the same conductive material as each other. Alternatively, the first conductive connection pattern 137a and the second conductive connection pattern 137b may include different conductive materials.

The display unit TU and the wiring substrate 205 may be electrically connected to each other via the second conductive connection pattern 137b of the double spacer pattern 135 connected to the link wire line LL of the wiring substrate 205 and the first conductive connection pattern 137a of the double spacer pattern 135 connected to the interlayer wiring line 130.

Moreover, the display unit TU and the wiring substrate 205 may be bonded to each other while the display unit TU and the wiring substrate 205 contact a relatively wide lower surface of the first spacer pattern 135a and a relatively wide upper surface of the second spacer pattern 135b of the double spacer pattern 135, respectively, thereby maintaining a stable binding force between the display unit TU and the wiring substrate 205.

FIG. 9 is a cross-sectional view showing a boundary area between adjacent display units in a display device according to an exemplary embodiment of the present disclosure. In FIG. 9, for the convenience of illustration, it is illustrated that in each of the display units TU1 and TU2, components other than each of bonding members BC1 and BC2 and the light-emitting element ED are omitted. In the drawing, only a configuration in which two display units TU1 and TU2 are disposed is presented. However, the present disclosure is not limited thereto. For example, another display unit may be disposed adjacent to one side of each of the display units.

Moreover, each of the display units TU1 and TU2, each of the bonding members BC1 and BC2 and the light-emitting element ED may have the same configurations as those of the display unit TU, the bonding member BC and the light-emitting element ED according to FIG. 5, respectively. Accordingly, the same components may be briefly described or descriptions thereof may be omitted.

The light-emitting element ED and a thin-film transistor for driving the light-emitting element ED may be disposed in each of the first display unit TU1 and the second display unit TU2 according to an exemplary embodiment of the present disclosure. The first display unit TU1 and the second display unit TU2 may be bonded and connected to the link wire line LL of the wiring substrate 205 via the first bonding member BC1 and the second bonding member BC2, respectively. The first bonding member BC1 and the second bonding member BC2 may have the same height such that a spacing between the first display unit TU1 and the wiring substrate 205 and a spacing between the second display unit TU2 and the wiring substrate 205 are equal to each other.

A plurality of outer bonding members BR1 may be disposed at an edge of the first display unit TU1. A plurality of outer bonding members BR2 may be disposed at an edge of the second display unit TU2. The outer bonding members BR1 and BR2 may be disposed outwardly of the bonding members BC1 and BC2, respectively.

The outer bonding members BR1 and BR2 may include the first outer bonding member BR1 disposed at the edge of at least one surface of the first display unit TU1, and the second outer bonding member BR2 disposed on an edge of at least one surface of the second display unit TU2.

The first and second outer bonding members BR1 and BR2 may respectively include first and second barrier patterns DM1 and DM2 and first and second insulating adhesive patterns IB1 and IB2 respectively disposed on upper surfaces of the first and second barrier patterns DM1 and DM2. Each of the first and second barrier patterns DM1 and DM2 may serve to block permeation of moisture from the outside, and may include an insulating material such as silicon oxide (SiOx) or silicon nitride (SiNx). However, the present disclosure is not limited thereto.

Each of the first and second barrier patterns DM1 and DM2 may have the same shape as that of the spacer pattern 135 of each of the bonding members BC1 and BC2. However, the present disclosure is not limited thereto. For example, each of the first and second barrier patterns DM1 and DM2 may include a rectangular prism or a cylindrical shape. The first and second insulating adhesive patterns IB1 and IB2 may include an insulating adhesive material. For example, each of the first and second insulating adhesive patterns IB1 and IB2 may include a silicone pressure sensitive adhesive (PSA). However, the present disclosure is not limited thereto. The first and second insulating adhesive patterns IB1 and IB2 may further improve adhesion between the display units TU1 and TU2 and the wiring substrate 205, respectively.

Moreover, the first and second outer bonding members BR1 and BR2 may have the same height as that of each of the bonding members BC1 and BC2 so that spacings between the display units TU1 and TU2 and the wiring substrate 205 may be maintained to be equal to each other.

In one example, the display device according to the present disclosure may include a configuration to prevent or reduce the boundary area (a seam area) between adjacent display units from being visible to the user to further improve image continuity and thus improve image quality. This will be described below with reference to the drawings.

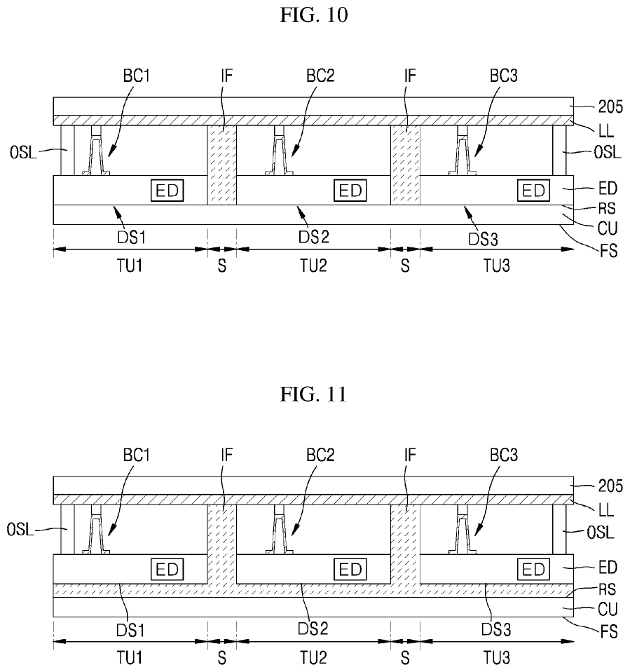

FIG. 10 is a cross-sectional view showing a boundary area between adjacent display units in a display device according to another exemplary embodiment of the present disclosure. FIG. 10 is the same as the display device of FIG. 9 except for a refractive index matching layer and an outer sealing portion. Thus, differences therebetween will be mainly described.

In FIG. 10, for convenience of illustration, it is illustrated that in each of the display units TU1, TU2 and TU3, components other than each of bonding members BC1, BC2 and BC3 and the light-emitting element ED are omitted. Moreover, each of the display units TU1, TU2 and TU3, each of the bonding members BC1, BC2 and BC3 and the light-emitting element ED in FIG. 10 may have the same configurations as those of the display unit TU, the bonding member BC and the light-emitting element ED according to FIG. 5, respectively. Accordingly, the same components may be briefly described or descriptions thereof may be omitted.

The light-emitting element ED and the thin-film transistor for driving the light-emitting element ED may be disposed in each of the first display unit TU1, the second display unit TU2, and the third display unit TU3 according to another exemplary embodiment of the present disclosure. Display surfaces DS1, DS2, and DS3 of the first display unit TU1, the second display unit TU2, and the third display unit TU3 may be in contact with a rear surface RS of a cover substrate CU. Light emitted from the light-emitting element ED may be emitted toward a display surface FS opposite to the rear surface RS of the cover substrate CU.

The first display unit TU1, the second display unit TU2, and the third display unit TU3 may be bonded and connected to the link wire line LL of the wiring substrate 205 via the first bonding member BC1, the second bonding member BC2, and the third bonding member BC3, respectively. The first bonding member BC1 to the third bonding member BC3 may have the same height such that spacings between the first display unit TU1 to the third display unit TU3 and the wiring substrate 205 may be maintained to be equal to each other.

The first display unit TU1, the second display unit TU2, and the third display unit TU3 may be arranged in a consecutive manner and may contact each other. Moreover, each of the first display unit TU1 and the third display unit TU3 may be defined as an outermost display unit disposed at an outermost area, while the second display unit TU2 may be defined as a middle display unit disposed therebetween.

The outer sealing portion OSL may be disposed at an edge of each of the first display unit TU1 and the third display unit TU3. For example, the outer sealing portion OSL may be disposed at the outermost edge of each of the first display unit TU1 and the third display unit TU3. The outer sealing portions SL serve to seal the display units TU1, TU2, and TU3 while the outer sealing portions SL together with the bonding members BC1, BC2, and BC3 maintain the spacing between the display units TU1, TU2, and TU3 and the wiring substrate 205. Thus, permeation of moisture or particles from the outside into the display units TU1, TU2, and TU3 may be prevented or reduced.

The outer sealing portions SL may have the same height as that of each of the bonding members BC1, BC2, and BC3 so as to maintain the spacings between the display units TU1, TU2, and TU3 and the wiring substrate 205 to be equal to each other.

A seam area S as the boundary area between adjacent ones of the display units TU1, TU2, and TU3 may be filled with a refractive index matching layer (index matching filler) IF having a refractive index similar to or (substantially) equal to that of the material constituting each of the display unit TU, the cover substrate CU, and the wiring substrate 205. For example, the cover substrate CU and the wiring substrate 205 may include a transparent material such as glass or plastic. In this case, the refractive index matching layer IF may include a material made of a transparent material.

The refractive index matching layer IF may have a refractive index in a range of 1.45 to 2.0 as a range of a refractive index (n) of glass. Moreover, the refractive index matching layer IF may have a light transmittance of 90% or greater in a visible light region. The refractive index matching layer IF may include an optical adhesive material. For example, the refractive index matching layer IF may include an OCA (Optically Clear Adhesive) or an OCR (Optically Clear Resin). The refractive index matching layer IF may include a material containing an acryl, silicone, or urethane-based component.

As the refractive index matching layer IF has adhesiveness, loss or reflection of light due to a circuit element such as the thin-film transistor may be minimized while bonding strength between each of the display units TU1, TU2, TU3 and the wiring substrate 205 may be maintained. Moreover, the refractive index matching layer IF may prevent or reduce variation in the index of refraction from occurring in the seam area S between the cover substrate CU and the wiring substrate 205. This may prevent or reduce the user from recognizing the seam area S, thereby preventing or reducing image quality from deteriorating.

FIG. 11 is a cross-sectional view showing a boundary area between adjacent display units in a display device according to still another exemplary embodiment of the present disclosure. FIG. 11 is the same as the display device of FIG. 10 except for a structure of the refractive index matching layer. Thus, differences therebetween will be mainly described, and the same components may be briefly described or descriptions thereof may be omitted.

In FIG. 11, for convenience of illustration, it is illustrated that in each of the display units TU1, TU2 and TU3, components other than each of bonding members BC1, BC2 and BC3 and the light-emitting element ED are omitted. Moreover, each of the display units TU1, TU2 and TU3, each of the bonding members BC1, BC2 and BC3 and the light-emitting element ED in FIG. 11 may have the same configurations as those of the display unit TU, the bonding member BC and the light-emitting element ED according to FIG. 6, respectively. Accordingly, the same components may be briefly described or descriptions thereof may be omitted.

According to still another exemplary embodiment of the present disclosure, the refractive index matching layer IF may fill the seam area S and may extend along and on the display surfaces DS1, DS2, and DS3 of the first display unit TU1, the second display unit TU2, and the third display unit TU3. The refractive index matching layer IF may have an increased contact area in contact with the rear surface RS of the cover substrate CU. For example, the refractive index matching layer IF extending along and on the display surfaces DS1, DS2, and DS3 of the first display unit TU1, the second display unit TU2, and the third display unit TU3 may have the same area size as an area size of the cover substrate CU. Accordingly, an edge of the refractive index matching layer IF may align with an edge of the cover substrate CU.

As the area size of the refractive index matching layer IF having the refractive index similar to that of the material constituting each of the cover substrate CU and the wiring substrate 205 increases, the seam area S may be further prevented or reduced from being recognized by the user, such that the image quality may be improved.

According to the embodiments of the present disclosure, the seam area is filled with the refractive index matching layer IF having a refractive index and light transmittance similar to those of glass and including a transparent material, such that the seam area as the boundary area between adjacent display units is invisible to the user, and thus the image immersion of the user and image quality may be improved.

Thus, the bezel area is disposed in a minimal space, or a zero bezel area in which substantially no bezel area exists is realized.

Moreover, the wiring substrate and each of the plurality of display units are electrically connected to each other and are bonded to each other using the bonding member. Thus, a plurality of processes for forming a side surface line may be omitted such that the process optimization may be realized.

Moreover, the plurality of transparent display units may be arranged on a transparent wiring substrate and may be electrically connected and be bonded to the transparent wiring substrate using the bonding members. In this way, a large-area transparent tiling display apparatus may be implemented.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A display device comprising:
a wiring substrate on which a plurality of link wire lines are disposed;
a plurality of display units including a plurality of light-emitting elements and a plurality of signal lines, respectively, wherein the plurality of display units are disposed on the wiring substrate and are spaced apart from each other;
a plurality of bonding members each disposed between the wiring substrate and a corresponding one of the plurality of display units, so as to electrically connect corresponding one or more of the plurality of link wire lines and corresponding one or more of the plurality of signal lines to each other; and
a refractive index matching layer filling a boundary area between adjacent ones of the plurality of display units.

2. The display device of claim 1, wherein the wiring substrate is comprised of a single substrate, and wherein the plurality of display units are disposed on the wiring substrate and are arranged so as to be spaced apart from each other in each of transverse and longitudinal directions of the wiring substrate.

3. The display device of claim 1, wherein each of the bonding members includes:
a spacer pattern;
a conductive connection pattern covering at least an outer surface of the spacer pattern; and
an adhesive pattern disposed on the conductive connection pattern and contacting a corresponding one of the link wire lines.

4. The display device of claim 1, wherein each of the bonding members includes:
a spacer pattern; and
a conductive connection pattern covering an upper surface and an outer side surface of the spacer pattern.

5. The display device of claim 3, wherein the spacer pattern has a taper shape in which a width of a lower surface thereof in contact with a corresponding one of the display units is larger than a width of an upper surface thereof in contact with a corresponding one of the link wire lines.

6. The display device of claim 1, wherein each of the bonding members includes:
a double spacer pattern including:
a first spacer pattern in contact with a corresponding one of the display units; and
a second spacer pattern disposed on the first spacer pattern and contacting a corresponding one of the link wire lines; and
a double conductive connection pattern including:
a first conductive connection pattern covering an upper surface and an outer side surface of the first spacer pattern; and
a second conductive connection pattern covering a lower surface and an outer side surface of the second spacer pattern, the second conductive connection pattern being in contact with the first conductive connection pattern,
wherein the upper surface of the first spacer pattern and the lower surface of the second spacer pattern are positioned so as to face each other,
wherein the first spacer pattern has a taper shape in which a width of a lower surface thereof in contact with the corresponding one of the display units is larger than a width of the upper surface thereof,
wherein the second spacer pattern has a reverse taper shape in which a width of an upper surface thereof contacting the corresponding one of the link wire lines is larger than the lower surface thereof.

7. The display device of claim 1, further comprising a filler disposed between the wiring substrate and the display units, wherein the filler includes a transparent resin.

8. The display device of claim 1, wherein the display device further comprises:
a circuit film disposed on at least one side end of the wiring substrate, and connected to one or more of the link wire lines;
an integrated circuit chip mounted on the circuit film for transmitting a driving signal to one or more of the plurality of display units; and
a printed circuit board connected to the circuit film.

9. The display device of claim 1, further comprising an outer sealing portion disposed at an edge of an outermost display unit among the plurality of display units, the sealing portion disposed between the wiring substrate and the outermost display unit.

10. The display device of claim 1, wherein each of the plurality of display units further includes an outer bonding member disposed more outwardly toward an edge of the display device than the bonding member and between the wiring substrate and the corresponding one of the display units, wherein the outer bonding member includes an insulating material.

11. The display device of claim 10, wherein the outer bonding member includes a barrier pattern, and an insulating adhesive pattern disposed on an upper surface of the barrier pattern,
wherein the outer bonding member has a same height as a height of the bonding member.

12. The display device of claim 1, further comprising a cover substrate disposed on display surfaces of the plurality of display units,
wherein one surface of the refractive index matching layer is in contact with the cover substrate.

13. The display device of claim 12, wherein the refractive index matching layer includes a material with a refractive index and a light transmittance similar to a refractive index and a light transmittance, respectively, of each of the display units, the wiring substrate or the cover substrate.

14. The display device of claim 13, wherein the refractive index matching layer includes an optical clear adhesive (OCA) or an optical clear resin (OCR).

15. The display device of claim 12, wherein the refractive index matching layer fills the boundary area between adjacent ones of the plurality of display units, and extends along and on a display surface of each of the plurality of display units,
wherein an edge of the refractive index matching layer is aligned with an edge of the cover substrate.

16. A display device, comprising:
a wiring substrate; and
a display unit disposed on the wiring substrate comprising:
a plurality of sub-pixels each including one or more micro-LEDs including inorganic material and a plurality of signal lines; and
a plurality of transmissive areas adjacent to the sub-pixels, the transmissive areas configured to transmit external light from a first side of the display device to a second side of the display device.

17. The display device of claim 16, further comprising:
a plurality of data lines disposed along and between the transmissive areas;
a first voltage supply line disposed on a first side of a group of sub-pixels along the data lines; and
a second voltage supply line disposed on a second side of the group of sub-pixels along the data lines.

18. The display device of claim 16, wherein the display unit includes a plurality of first display units and a plurality of second display units, each disposed alternately and spaced apart from each other.

19. The display device of claim 18, further comprising:
a link wire line disposed on the wiring substrate;
a first bonding member disposed between and in contact with the first display unit and the wiring substrate, the first bonding member electrically connecting the link wire line and one or more of the signal lines of the first display unit; and
a second bonding member disposed between and in contact with the second display unit and the wiring substrate, the second bonding member electrically connecting the link wire line and one or more of the signal lines of the second display unit.

20. The display device of claim 19, wherein the first bonding member comprises:
a spacer pattern disposed on the one or more of the signal lines of the first display unit;
a conductive connection pattern covering an outer surface of the spacer pattern and in contact with the one or more of the signal lines of the first display unit; and
an adhesive pattern disposed on the conductive connection pattern and contacting the link wire line, the adhesive pattern being conductive.

21. The display device of claim 20, wherein the conductive connection pattern covers an upper surface and an outer side surface of the spacer pattern.

22. The display device of claim 20, wherein the spacer pattern has a taper shape in which a width of a lower surface thereof in contact with the first display unit is larger than a width of an upper surface thereof in contact with adhesive pattern.

23. The display device of claim 19, wherein the first bonding member comprises:
a double spacer pattern including:
a first spacer pattern in contact with the first display unit; and
a second spacer pattern disposed on the first spacer pattern and contacting the link wire line; and
a double conductive connection pattern including:
a first conductive connection pattern covering an upper surface and an outer side surface of the first spacer pattern; and
a second conductive connection pattern covering a lower surface and an outer side surface of the second spacer pattern, the second conductive connection pattern being in contact with the first conductive connection pattern,
wherein the upper surface of the first spacer pattern and the lower surface of the second spacer pattern are positioned to face each other,
wherein the first spacer pattern has a taper shape in which a width of a lower surface thereof in contact with the first display unit is larger than a width of the upper surface thereof, and
wherein the second spacer pattern has a reverse taper shape in which a width of an upper surface thereof contacting the link wire line is larger than the lower surface thereof.

24. The display device of claim 18, further comprising a refractive index matching layer filling a boundary area between first display unit and the second display unit.

25. The display device of claim 24, wherein the refractive index matching layer includes an optical clear adhesive (OCA) or an optical clear resin (OCR).

26. The display device of claim 24, wherein the refractive index matching layer fills a boundary area between the first display unit and the second display unit, and extends along and on a display surface of the first display unit and the second display unit.

27. The display device of claim 19, further comprising a filler disposed between the wiring substrate and the first and second display units, the filler including a transparent resin.

28. The display device of claim 19, further comprising an outer sealing portion disposed at an edge of an outermost one of the first and second display units, the sealing portion disposed between the wiring substrate and the outermost one of the first and second display units.

29. The display device of claim 19, wherein the first display unit further includes an outer bonding member disposed more outwardly toward an edge of the first display device than the first bonding member and between the wiring substrate and the first display unit, the outer bonding member including an insulating material.

30. The display device of claim 29, wherein the outer bonding member includes a barrier pattern and an insulating adhesive pattern disposed on an upper surface of the barrier pattern, and wherein the outer bonding member has a same height as a height of the first bonding member.

31. The display device of claim 24, further comprising a cover substrate disposed on display surfaces of the first and second display units, and wherein one surface of the refractive index matching layer is in contact with the cover substrate.

32. A display device, comprising:
a plurality of display units including a first display unit and a second display unit disposed laterally spaced apart from the first display unit, each of the first and second display units comprising: a substrate on which a plurality of thin film transistors are disposed;
a passivation layer disposed on the thin film transistors and including insulating material;
an adhesive layer disposed on at least a part of the passivation layer;
one or more micro-LED chips each including a micro-LED made of inorganic material and attached to the passivation layer by the adhesive layer;
one or more protective patterns each disposed on a side surface or at least a part of a top surface of the micro-LED chip.

33. The display device of claim 32, wherein the protective pattern is disposed between the passivation layer and the micro-LED chip.

34. The display device of claim 33, wherein the protective pattern includes inorganic material.

35. The display device of claim 32, the first display units and the second display units comprise a plurality of sub-pixels and a plurality of transmissive areas adjacent to the sub-pixels, the transmissive areas configured to transmit external light from a first side of the display device to a second side of the display device.
